(19) United States
(12) Patent Application Publication
(10) Pub. No.: US 2011/0100465 A1
(43) Pub. Date: May 5, 2011

(54) Organic Solar Cell with Oriented Distribution of Carriers and Manufacturing Method of the Same

(76) Inventors: Sheng-Fu Horng, Hsinchu City (TW); Hsin-Fei Meng, Hsinchu City (TW); Ming-Kun Lee, Hsinchu City (TW); Jen-Chun Wang, Hsinchu City (TW); Tsung-Hang Kuo, Hsinchu City (TW)

(21) Appl. No.: 12/751,172

(22) Filed: Mar. 31, 2010

(30) Foreign Application Priority Data
Nov. 4, 2009 (TW) 098137461

(51) Int. Cl. H01L 51/46; H01L 51/48

(52) U.S. Cl. 136/263; 438/82; 257/E51.026

(57) ABSTRACT

The present invention provides an organic solar cell with oriented distribution of carriers, which forming variation of distribution of electron donors and electron acceptors between active sub-layers of an active layer by utilizing buffer layer method, for improving carrier extraction efficiency and thus effectively enhancing performance of the organic solar. The present invention also provides a method for manufacturing an organic solar cell with oriented distribution of carriers.

### FIELD OF THE INVENTION

The present invention is generally related to the field of the solar cell and, more particularly, to an organic solar cell including multi-layer structure, for forming oriented distribution of electron donors and electron acceptors.

### DESCRIPTION OF THE PRIOR ART

Semiconducting conjugated polymers exhibit advantages such as cost effectiveness, feasibility to scale up, convenience for coating, moderate flexibility, etc. Therefore, in recent years, the industries have actively investigated during the development of the related technologies, which comprising organic light emitting diode (OLED), organic thin film transistor, organic solar cell, etc. When fabricating those on plastic substrates, further advantages such as flexibility and light-weightiness can be obtained for increasing the applicability. Furthermore, because of its flexibility, continuous roll-to-roll processing might be employed to lower the processing cost and increase the final throughput.

Among these applications, solution-processed organic photovoltaics have wider application and lower fabrication cost comparing to its inorganic counterpart. Thus, they become highly-concerned about and getting new development unceasingly. However, there are some limiting factors which come from the natural properties of the polymer material, such as lower carrier (electron/electric hole) mobility, higher exciton binding energy, and the interlayer mixing phenomenon. Therefore, the organic solar cell, especially the polymer organic solar cell, generally has the shortcomings of owning low light absorption efficiency and low carrier extraction efficiency, and they may be viewed as a bottleneck upon the development of the organic solar cell that is not yet be overcome.

The applicant of the present invention has provided a method for producing multilayer organic molecular photoelectric elements, the method comprising: (1) a step of applying a solution comprising organic molecules A on a clean, transparent substrate made of glass or plastic, to form a layer of organic molecule A; (2) a step of applying a solution comprising buffer agent on the layer of organic molecule A, to form a non-permanent buffer layer; (3) a step of applying a solution comprising organic molecule B on the non-permanent buffer layer, to form a layer of organic molecule B; (4) optionally, a step of removing the non-permanent buffer layer, and (5) repeating steps (2), (3) and (4) to obtain a photoelectric element with two or more layers of organic molecules.

The applicant of the present invention provides the method for producing multilayer organic molecular photoelectric elements utilizing the above-mentioned method (for brevity, the method is called “buffer layer method” thereafter), and the multilayer organic molecular photoelectric elements can thus be manufactured by simpler processes. However, in the specification of the disclosed buffer layer method, it is not provided about how to apply the buffer layer method on implementing the organic solar cell and how to overcome the shortcomings of the light absorption efficiency and carrier extraction efficiency therein.

Therefore, the applicant utilizes the above-mentioned buffer layer method and further provides an organic solar cell with oriented distribution of carriers in the embodiment of the present invention. The manufacturing method and related applications are also provided, and they will be described thoroughly in the following description.

### SUMMARY OF THE INVENTION

One of the objects of the embodiments of the present invention is to provide a method for manufacturing an organic solar cell with oriented distribution of carriers, to form an active layer comprising concentration variation of electron donors and electron acceptors utilizing a buffer layer method.

Another object of the embodiments of the present invention is to provide an organic solar cell with oriented distribution of carriers, wherein its active layer comprises multilayer active sub-layers comprising concentration variation of electron donors and electron acceptors.

Still another object of the embodiments of the present invention is to provide an organic solar system with oriented distribution of carriers, to provide electric power to at least one application device from an organic solar cell with oriented distribution of carriers, whereby the at least one application device receiving electric power to operate. The at least one application device may widely comprise the various electrical products in the markets, and the organic solar cell can be coupled to the electrical product externally or internally.

In one aspect of the embodiments of the present invention, a method for manufacturing an organic solar cell with oriented distribution of carriers is provided, the method comprising: forming at least one hole transporting layer on at least one anode layer; forming at least one active layer on the at least one hole transporting layer, wherein the at least one active layer comprises a plurality of active sub-layers; steps to form the plurality of active sub-layers comprising: (a) coating a first solution comprising electron donors and electron acceptors on the hole transporting layer, for forming a first active sub-layer; (b) forming a second solution comprising a buffer agent on the first active sub-layer, for forming a non-permanent buffer layer; (c) coating a third solution comprising electron donors and electron acceptors on the non-permanent buffer layer, for forming a second active sub-layer; wherein ratio of electron donors to electron acceptors in the second active sub-layer is lower than that of the first active sub-layer; (d) repeating the steps of (b) and (c) to form the plurality of active sub-layers; and forming at least one cathode layer on the at least one active layer.

In another aspect of the embodiments of the present invention, an organic solar cell with oriented distribution of carriers is provided, the organic solar cell comprising: at least one anode layer; at least one hole transporting layer formed on the at least one anode layer, for facilitating electron hole transportation; at least one active layer formed on the at least one hole transporting layer, the at least one active layer comprising a plurality of active sub-layers; wherein each of the plurality of active sub-layers comprise electron donors and electron acceptors; ratio of electron donors to electron acceptors in one of the plurality of active sub-layers having farther distance between the at least one anode layer is lower than which in one of the plurality of active sub-layers having closer distance between the at least one anode layer, for providing oriented distribution of carriers; and at least one cathode layer formed on the at least one active layer.

One of the advantages of the embodiments of the present invention is that the multilayer without interlayer miscibility phenomenon, more particular, the active sub-layers without interlayer miscibility phenomenon, can be formed utilizing the buffer layer method, to form an active layer with concentration variation of electron donors and electron acceptors, i.e., the active layer with oriented distribution of carriers, and the organic solar cell and organic solar system with oriented distribution of carriers are also provided.

Another aspect of the embodiments of the present invention is that the potential gradients of carriers can be formed upon the variations of the ratios of the electron donors to the electron acceptors between the different active sub-layers. Upon weak forward bias and light bias, the carrier extraction efficiency is obviously improved, and the efficiencies of the organic solar cell and/or the organic solar system are also improved. Further, the performances upon various parameters, such as parallel resistance, short current, fill factor and/or energy conversion efficiency are also improved.

The organic solar cell has the advantages of such as light-weightiness, cost effectiveness, and feasibility to scale up, and its efficiency is further increased in the embodiments of the present invention, for providing better practicability which is quite important nowadays with worsened energy crisis. In addition, within the intense technology developments, the efficiency improvement provided by the embodiments of the present invention is not easily accomplished by the ordinary skill in the art and is thus not obvious. The features and advantages of the embodiments of the present invention can be better understood through the following descriptions and the accompanying figures.

### BRIEF DESCRIPTION OF THE DRAWINGS

FIG. 1 illustrates the organic solar system according to the embodiments of the present invention;

FIG. 2 illustrates the structure of the organic solar cell according to the embodiments of the present invention;

FIG. 3 illustrates the structure of the organic solar cell according to the embodiments of the present invention;

FIG. 4 illustrates the structure of the organic solar cell according to the embodiments of the present invention;

FIGS. 5A-5F illustrate the processes for manufacturing the organic solar cell according to the embodiments of the present invention;

FIG. 6 illustrates the relationship diagram of the voltage to the current density according to the embodiments of the present invention;

FIG. 7 illustrates the relationship diagram of the voltage to the current density according to the embodiments of the present invention;

FIG. 8 illustrates the relationship diagram of the wavelength to the incident photon-to-electron conversion efficiency according to the embodiments of the present invention;

FIG. 9 illustrates the relationship diagram of the wavelength to the incident photon-to-electron conversion efficiency according to the embodiments of the present invention;

FIG. 10 illustrates the relationship diagram of the wavelength to the incident photon-to-electron conversion efficiency according to the embodiments of the present invention; and

FIG. 11 illustrates the processes for manufacturing the organic solar cell with oriented-distribution of carriers according to the embodiments of the present invention.

### DESCRIPTION OF THE PREFERRED EMBODIMENT

In the embodiments of the present invention, a multilayer coating process is applied to the active layer (light absorption layer), for manufacturing an organic solar cell with oriented-distribution of electron donors and electron acceptors. The probability of recombination of the carriers (including electrons and holes) before being transported to the corresponding electrodes (anode or cathode) is thus lowered.

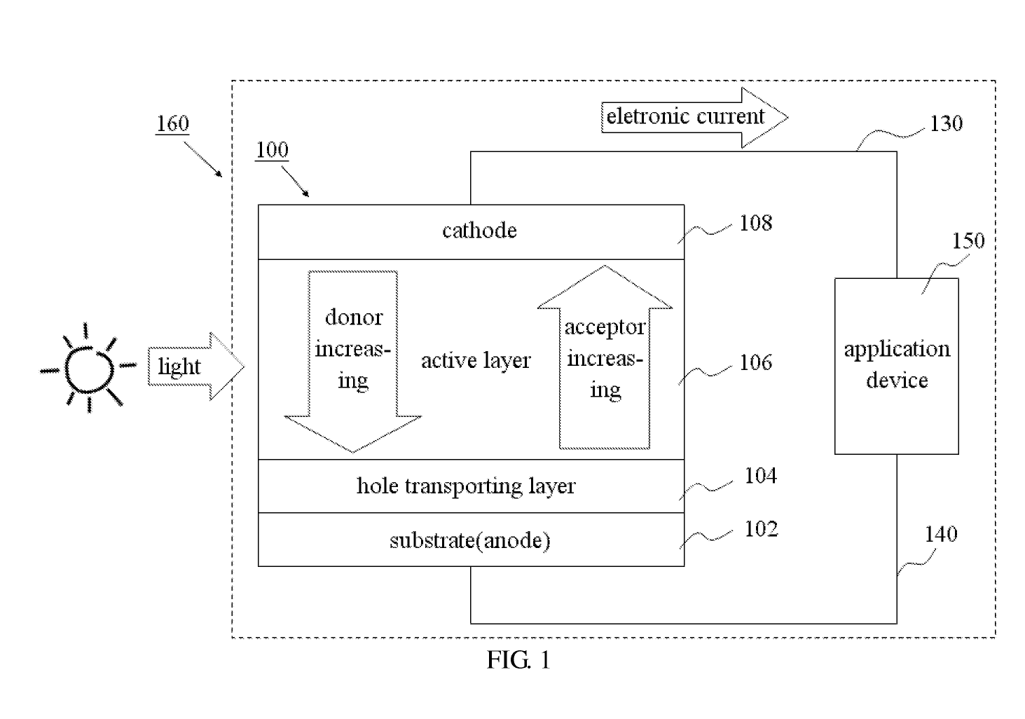

FIG. 1 shows the organic solar system with multilayer structure according to the embodiment of the present invention. The organic solar cell 100 comprises a substrate 102 formed on the bottom thereof, as an anode of the organic solar cell 100; a hole transporting layer (HTL) 104 formed on the substrate 102, for facilitating transportation of the electron holes; an active layer 106 formed on the HTL 104, for absorbing light energy (from the sun or other light sources), and therefore called a “light absorption layer”; and a cathode 108 formed on the active layer 106, for providing electronic currents to an application device 150. The cathode 108 and substrate (anode) 102 of the organic solar cell 100 are connected to the corresponding electrodes of the application device 150 via conducting wires 130 and 140, for driving the application device 150 to operate utilizing the electric power generated by the organic solar cell absorbing the light energy. In the other words, the organic solar cell 100, the conducting wires 130 and 140, and the application device 150 can be viewed as a whole of an organic solar cell combined with an application device or an organic solar system 160. The organic solar system 160 may comprise a transportation device, a video/audio entertainment device, a medical device, etc. For example, it may comprise, but not limited to, a vehicle, a motorcycle, a computer, a notebook, a mobile phone, a personal digital assistant (PDA) or other stationary or mobile devices. In the different embodiments of the present invention, the organic solar cell 100 and the application device 150 of the organic solar system 160 can be implemented as separate parts, and the organic solar cell 100 can be externally connected to the application device 150; or the organic solar cell 100 can be integrated with the application device 150 as a whole, and the organic solar cell 100 can be embedded into the application device 150.

One feature of the embodiments of the present invention is the improvement of the active layer 106, as shown in FIG. 1. The active layer 106 is implemented by a buffer layer method in the embodiments of the present invention, for providing a multilayer coating and thus forming a multilayer structure with oriented distribution of electron donors and electron acceptors. The oriented distribution can be substantially classified as two variation tendencies which are related to the electron donor content and the electron acceptor content, respectively. In other words, the electron donor content is increasing from the top to the bottom (or decreasing from the bottom to the top), and the electron acceptor content is increasing from the bottom to the top (or decreasing from the top to the bottom), whereby the electrons and holes of the electron-hole pairs, generated form excitons within the active layer 106 excited by light, can be driven by the multilayer with oriented distribution of electron donors and electron acceptors and flowing to the corresponding cathode 108 and anode 102, respectively. The probability of the electron donors and the electron acceptors being recombined after separated is obviously lowered, and the carrier extraction efficiency of the organic solar cell 100 is thus improved. In other words, the light absorption efficiency of the organic solar cell 100 is improved. The measurements of the light absorption efficiency of the organic solar cell 100 according to some embodiments of the present invention are provided in the following description, and the performance improvement of the organic solar cell 100 with the above-mentioned multilayer structure is verified and supported by its external quantum efficiency measured by bias.

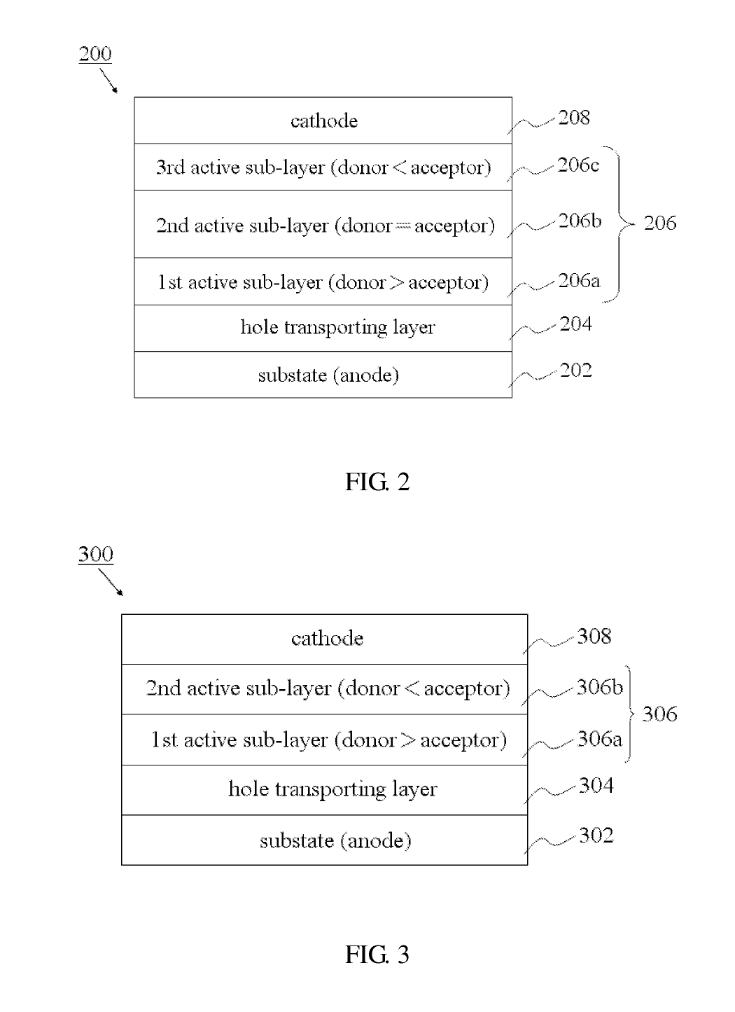

FIG. 2 illustrates an organic solar cell with multilayer structure according to the further embodiment of the present invention. For brevity, only the structure of the organic solar cell is shown in this figure, while other components, such as conducting wires, application device, etc., are not shown. Please refer to, but not limited to, the peripheral components described in FIG. 1. The organic solar cell 200 comprises a structure similar to that in FIG. 1, which comprises a substrate 202, a HTL 204, an active layer 206 and a cathode 208. In FIG. 2, the active layer 206 is split into a first active sub-layer 206a, a second active sub-layer 206b, and a third active sub-layer 206c. The distribution of electron donors and acceptors are different among the three layers, for providing multilayer structure with oriented distribution of electron donors and electron acceptors. In other words, the active layer 106 is more specifically implemented as the first active sub-layer 206a, the second active sub-layer 206b, and the third active sub-layer 206c. However, the present invention is not limited to this embodiment. More embodiments are provided in the following descriptions, and the present invention can be implemented by other different embodiments.

In FIG. 2, the first active sub-layer 206a is formed on the HTL 204, the second active sub-layer 206b is formed on the first active sub-layer 206a, and the third active sub-layer 206c is formed on the second active sub-layer 206b. Therefore, the first active sub-layer 206a is relatively closer to the substrate 202, while the third active sub-layer 206c is relatively closer to the cathode 208. For providing better performance, such as better carrier extraction efficiency and light absorption efficiency, the second active sub-layer 206b may comprise the material layer comprising the ratio of electron donors to electron acceptors as between about “2:1” to “0.5:1”. In contrast, the first active sub-layer 206a may comprise the “donor-rich” material layer which comprises the ratio of electron donors to electron acceptors as between about “2.1:1” to “10:1”. Further, the third active sub-layer 206c may comprise the “acceptor-rich” material layer which comprises the ratio of electron donors to electron acceptors as between “1:2.1” to “1:10”.

In contrast with the active layer within the organic solar cell implemented as three-layer structure with different electron donor content and electron acceptor content shown in FIG. 2, FIG. 3 shows another embodiment of implementing the organic solar cell with active layer comprising two-layer structure. In FIG. 3, the organic solar cell 300 comprises a similar structure with that in FIG. 1, which comprising a substrate 302, a HTL 304, an active layer 306, and a cathode 308. In FIG. 3, the active layer 306 is split into two layers, a first active sub-layer 306a, and a second active sub-layer 306b, which comprising different electron donor content and electron acceptor content, for providing two-layer structure with oriented distribution of electron donors and electron acceptors. In other words, in FIG. 3, the active layer 106 is more specifically implemented as the first active sub-layer 306a and the second active sub-layer 306b. The first active sub-layer 306a is formed on the HTL 304, and the second active sub-layer 306b is formed on the first active sub-layer 306a. Therefore, the first active sub-layer 306a is relatively closer to the substrate 302, and the second active sub-layer 306b is relatively closer to the cathode 308. For providing better performance, the second active sub-layer 306b may comprise the material layer comprising the ratio of electron donors to electron acceptors as between about “2:1” to “0.5:1”, which is “acceptor-rich”. In contrast, the first active sub-layer 306a may comprise the “donor-rich” material layer which comprising the ratio of electron donors to electron acceptors as between about “2.1:1” to “10:1”.

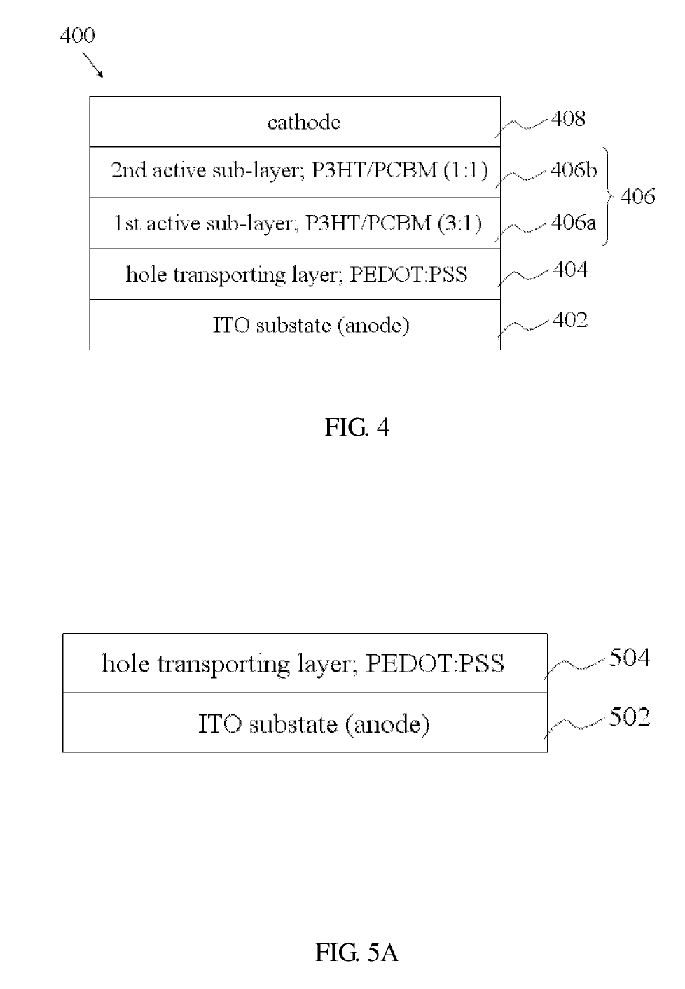

FIG. 4 shows the structure of the organic solar cell according to another embodiment of the present invention, wherein the organic solar cell 400 comprises a substrate 402, a HTL 404, an active layer 406, and a cathode 408. The active layer 406 is split into a first active sub-layer 406a and a second active sub-layer 406b. In this embodiment, the material of substrate 402 may comprise metal oxide or metal oxide containing dopants, while the material comprises, but not limited to, indium tin oxide (ITO), tin oxide, or fluorine-doped tin oxide. In preferred embodiments, the ITO is utilized. The material of the HTL 404 may comprise poly(3,4-ethylenedioxythiophene)poly(styrenesulfonate) (PEDOT:PSS). The material of the HTL 404 may comprise other materials, such as other doped conductive polymers. The first active sub-layer 406a and the second active sub-layer 406b may comprise at least two components, for providing as electron donors and electron acceptors. The material of the electron donors may comprise polymer, and organic conjugated polymer is preferred. The material may selected from the following group: polyacetylene, polyisothianaphtene (PITN), polythiophene (PT), polypyrrol (PPr), polyfluorene (PF), poly(p-phenylene) (PPP), derivatives of poly(phenylene vinylene) (PPV), poly(3-hexylthiophene-2,5-diyl) (P3HT), etc. In preferred embodiments, P3HT is selected. The electron acceptor may comprise poly(cyanophenylenevinylene), fullerene such as C60 and the functional derivatives (such as 1-(3-methoxycarbonyl)propyl-1-phenyl[6,6]C61 (PCBM)), organic compound, metal oxide, inorganic nano-particle (such as CdTe, CdSe, CdS, CuInS 2, CuInSe 2, etc.). In some preferred embodiments, PCBM is utilized. In some preferred embodiments, the polymer P3HT mixing small molecule PCBM (the “small molecule” refers to non-polymer) provides hetero-junction, for improving light absorption efficiency. Further, the content of P3HT and PCBM is not the same within the two layers. The ratio of P3HT to PCBM is about 3:1 in the first active sub-layer 406a, and the ratio of P3HT to PCBM is about 1:1 in the second active sub-layer. Therefore, among the first active layer 406a and the second active layer 406b, an oriented distribution of electron donors and electron acceptors is formed (the active layer having a decreasing electron donor content and an increasing electron acceptor content from the anode to the cathode is provided). The potential gradient is generated by the hetero-junction of the bulk material, for facilitating electrons and holes (i.e., the carriers) flowing to the corresponding electrodes. Furthermore, the material of the cathode 408 may comprise opaque metal, such as aluminum, calcium aluminum alloy, magnesium aluminum alloy, copper, gold, etc.

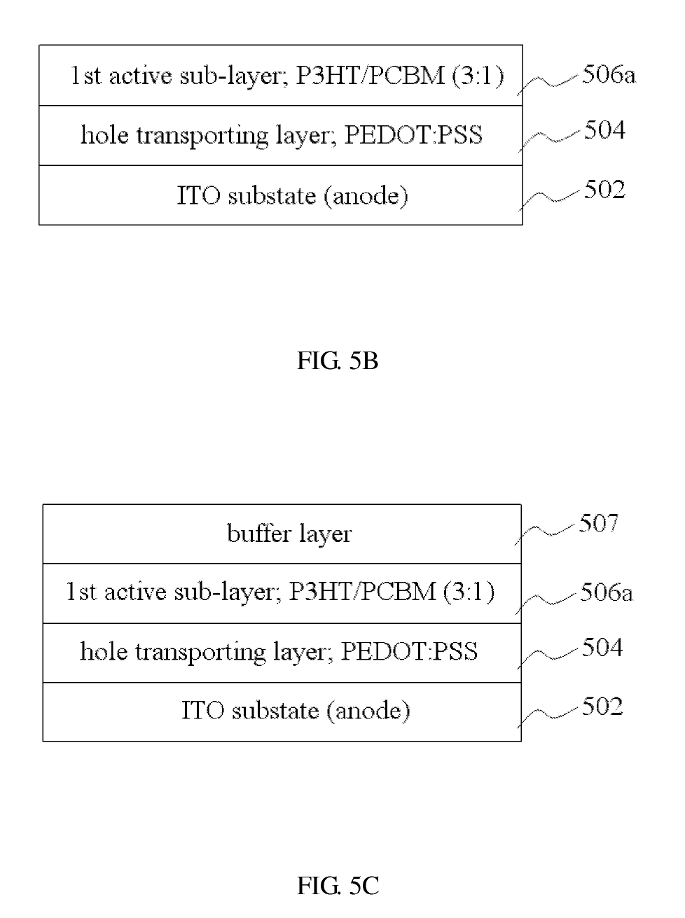

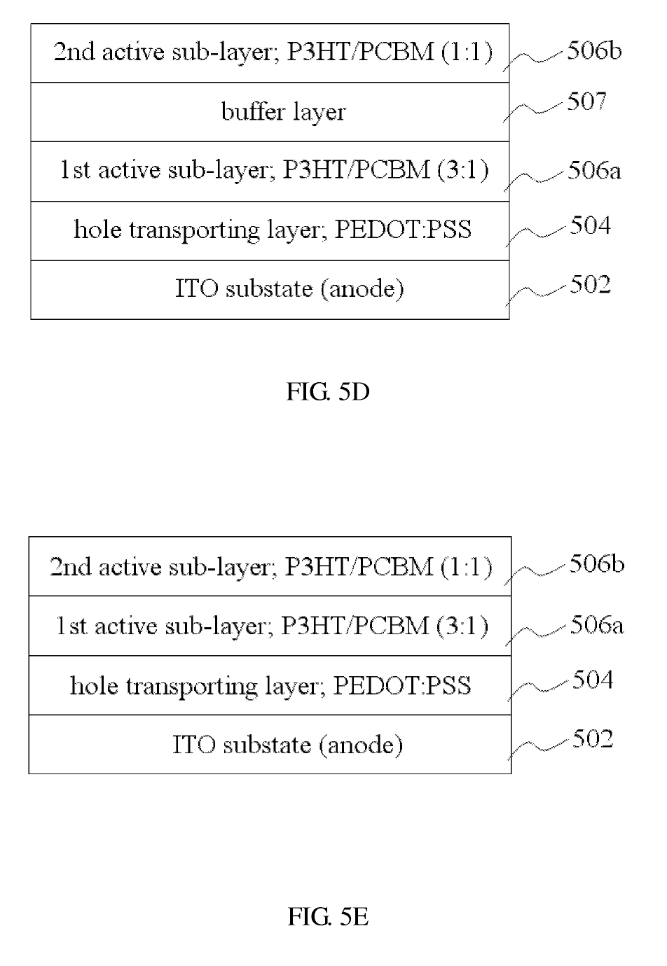

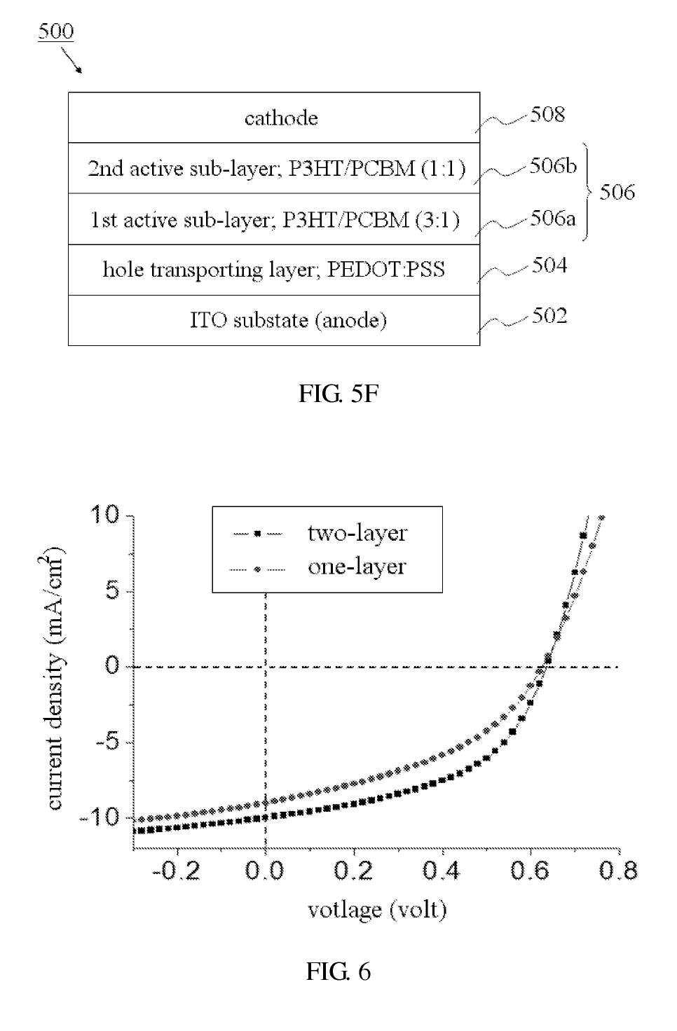

In the above description, several embodiments of the organic solar cell are provided, such as the active layer can be implemented as two active sub-layers or three active sub-layers. In fact, more sub-layers can be applied with the similar principle and/or processes in other embodiments. In the different embodiments of the present invention, different variations of the mixing ratio of electron donors to electron acceptors can be further provided, such as the variation of potential energy, for adapting to different demands. For purpose of being thoroughly understood, the two-layer structure is further explained in the following description, and the manufacturing method is shown as FIGS. 5A-5F.

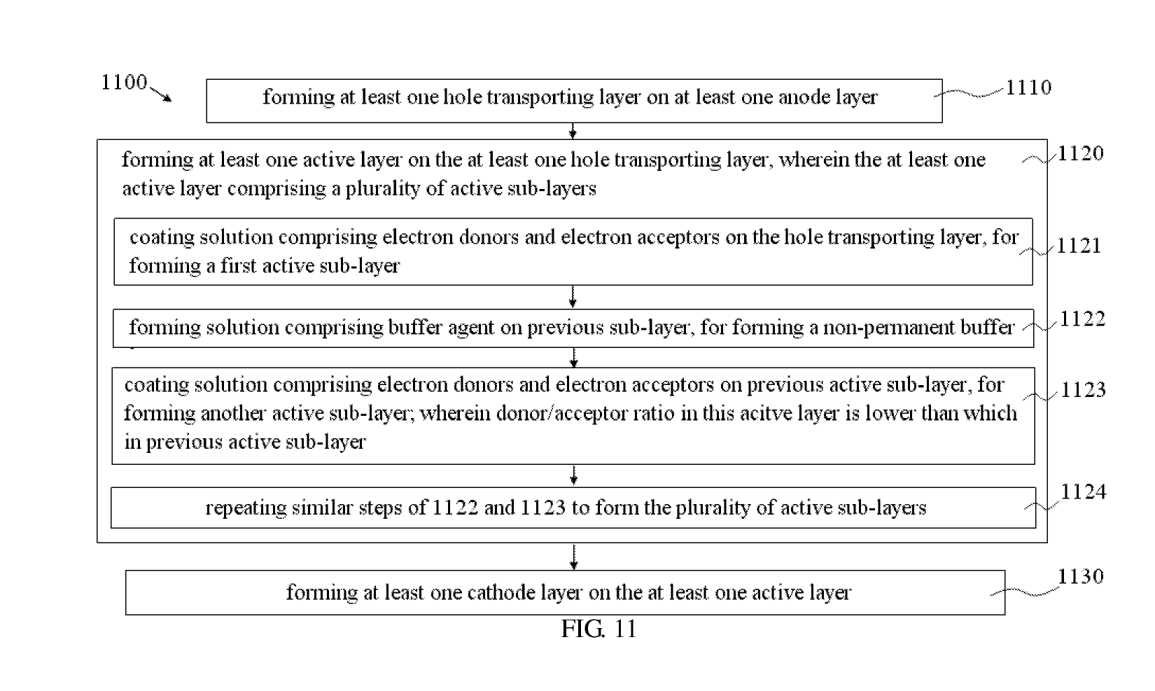

For manufacturing the organic solar cell with similar structure described in FIG. 4, the buffer layer method is applied in the embodiment of the present invention. The processes are described below, as shown the FIGS. 5A-5F. In FIG. 5A, the first process is preparing an ITO glass substrate 502. The ITO glass substrate 502 is rinsed with organic solvent, and a material of HTL (PEDOT:PSS) is coated on the ITO glass substrate 502 by spin coating, for forming a thin film of PEDOT mixing with PSS. The film is heated up to about 200° C. and baked at nitrogen environment maintaining about 5 minutes (the time, generally implemented with about 5 to 30 minutes, can be adjusted depending on different conditions), for forming HTL 504 on the ITO glass substrate 502. As shown in FIG. 5B, the solution comprising the donor/acceptor (P3HT/PCBM) ratio “3:1” is then coated on the HTL 504 by spin coating. In some embodiments, the concentration of the donors may be about 8.5 mg/ml, and the solvent may be toluene. The layer is heated up to about 140° C. and baked at nitrogen environment maintaining about 10 minutes (the time, generally implemented with about 5 to 30 minutes, can be adjusted depending on different conditions), for forming first active sub-layer 506a on the HTL 504. A buffer layer 507 is then formed on the first active sub-layer 506a by coating glycol solution utilizing spin coating. A second active sub-layer 506b (donor/acceptor ratio is about 1:1, donor concentration is about 17 mg/ml, and the solvent is toluene) is coating on the buffer layer 507 after coating the buffer layer 507, as shown in FIG. 5D. The layer is heated up to about 140° C. and baked at nitrogen environment maintaining about 10 minutes (the time, generally implemented with about 5 to 30 minutes, can be adjusted depending on different conditions). Wherein the content of the buffer 507 can be substantially removed during the baking processes (please refer to FIG. 5E). In the preferred embodiment of the present invention, the thicknesses of the first active sub-layer 506a and the second active sub-layer 506b are about, but not limited to, 80 nm and 220 nm, respectively, or the ratio may be about 4:11. As shown in FIG. 5F, the cathode 508 may be coated on the second active sub-layer 506b by implementing thermal evaporation. In preferred embodiment, the cathode comprises calcium layer and silver layer, and their thicknesses are about 50 nm and 80 nm, respectively. The following process is packaging which is not illustrated in the figures. It should be noted that although the same donors and acceptors are implemented among the different active sub-layers with different content ratios, but the invention is not limited to theses embodiments. The same purpose can be achieved by implementing different donors and acceptors among the different active sub-layers with different content ratio. The above embodiments are intended to provide clear description and explanation. Further, the ways of coating are not limited to spin coating. In the different embodiments of the present invention, the ways of coating may comprise, but not limited to, cast coating, spin coating, doctor blading, screen printing, ink jet printing, pad printing, slot die coating, gravure coating, knife-over-edge coating, meniscus coating, or the combinations thereof. FIG. 11 shows a method of manufacturing an organic solar cell with oriented distribution of carriers according to the embodiment of the present invention. The manufacturing method comprises: in the process 1110, forming at least one HTL on at least one anode layer; in the process 1120, forming at least one active layer on the at least one HTL, wherein the at least one active layer comprises a plurality of active sub-layers; in the process 1121, coating a solution comprising electron donors and electron acceptors on the HTL, for forming a first active sub-layer on the HTL; in the process 1122, coating a solution comprising buffer agent on previous active sub-layer, for forming a non-permanent buffer layer; in the process 1123, coating a solution comprising the electron donors and electron acceptors with donor/acceptor ratio lower than the ratio of electron donors to electron acceptors within the previous active sub-layer, for forming another active sub-layer on the previous active sub-layer; in the process 1124, repeating processes similar to the process 1122 and 1123, for forming the plurality of active sub-layers; and in the process 1130, forming at least one cathode layer on the at least one active layer. In the preferred embodiment, the manufacturing method 1100 of the organic solar cell with oriented distribution of carriers is proceeded within a glove box, whereby a low water and oxygen environment can thus be provided. For example, the water content is between about 0 to 10 ppm, while the oxygen content is between about 0 to 10 ppm. However, the above-mentioned conditions may slightly vary upon different selected material or environment.

The above paragraphs describe the manufacturing processes and the experimental conditions according to the embodiments of the present invention. However, it is for purpose of illustration but not to limit the scope of the present invention. It should be understood that some conditions may slightly change for adapting more applications.

Under the radiation of solar simulator “AM1.5G”, measurement result of the various parameters of the organic solar cells with the two-layer active layer structure and the one-layer active layer structure are provided as TAB. 1:

TABLE 1
parameters of one-layer and two-layer active layer structures

| Active | | | | | | |
|---|---|---|---|---|---|---|
| Layer | Rs | Rsh | Voc | | PCE | Iph |
| Structure | (Ωcm²) | (Ωcm²) | (V) | FF | (%) | (mA/cm²) |
| Two-layer | 14.6 | 407 | 0.63 | 48.7 | 3.12 | 10.4 |
| One-layer | 9.26 | 312 | 0.63 | 41.7 | 2.35 | 9.44 |

Wherein, Rs refers to series resistance; Rsh refers to shunt resistance; Voc refers to open circuit voltage which represents the measured electric voltage of the organic solar cell component when the load resistance R_{L} is about infinite; FF refers to fill factor, which is defined as

$$FF = \frac{{P}_{max}}{{I}_{sx} {V}_{oc}} = \frac{{I}_{max} {V}_{max}}{{I}_{sc} {V}_{oc}} ,$$

when maximum power of the organic solar cell is represented as Pₘₐₓ=IₘₐₓVₘₐₓ; PCE refers to power conversion efficiency, η, which is defined as the maximum output power divided by input light power,

$$η = \frac{{P}_{max}}{{P}_{in}} = \frac{FF \times {V}_{oc} \times {I}_{sc}}{{P}_{in}} ;$$

and Iph refers to the current can be generated by the organic solar cell. It can be obviously observed that various parameters such as Rs, Rsh, FF, PCE, and Iph of the two-layer organic solar cell are better than that of the one-layer organic solar cell.

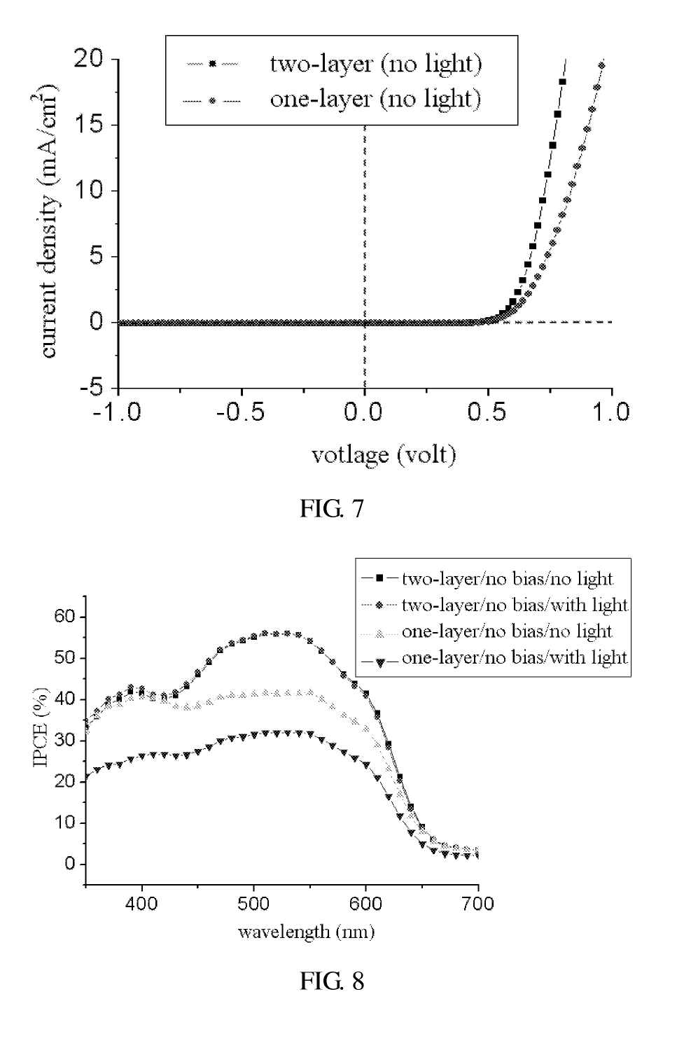

Further, voltage to current density relationship diagrams of the two-layer active layer organic solar cell 500 and the one-layer active layer organic solar cell with the radiation of “AM1.5G” and without the radiation are shown in FIGS. 6 and 7. Wherein, the curve inflection of the two-layer active layer structure of the organic solar cell is larger than that of the one-layer active layer structure of the organic solar cell. The donor/acceptor (P3HT/PCBM) ratio is about 1:1, the donor concentration is about 17 mg/ml, and the solvent is toluene. The heating condition is heating up to about 140° C. and maintaining about 20 minutes. The calcium and silver layers are coated on the active layer by implementing thermal evaporation, and the corresponding thicknesses are about 50 nm and 80 nm, respectively, for utilizing as cathodes. The thickness of the one-layer active layer is about 300 nm, and the thickness of the two-layer active layer 506 is substantially the same, for preventing influences upon the thicknesses. Further, the various experimental conditions are substantially the same, for measuring objectively. Whereby, it can be observed that the two-layer active layer structure having higher Isc and FF. Therefore, without changing the open circuit voltage, the component efficiency is still improved obviously. Further, from the parameters in TAB. 1, it could be assumed that the improvement of the Rsh is one of the major causes of the improvement of the component efficiency. Further, it can be observed that the photocurrent (the current under light radiation) is enlarged about 10%, which may be another major cause of the improvement of the component efficiency. In other aspect, it could be assumed that the improvement of the component efficiency is not depending on inhibiting the dark current (the current without light radiation) flowing reverse to the photocurrent. In contrast, the two-layer active layer structure may have higher dark current. Therefore, it may be assumed that the improvement of the component efficiency may be credited for the carriers generated by the radiation having better exaction efficiency within the two-layer active structure of the organic solar cell. However, the above description is not for limiting the present invention but for providing detailed explanation, for facilitating the ordinary skill in the art to understand the features and advantages of the present invention.

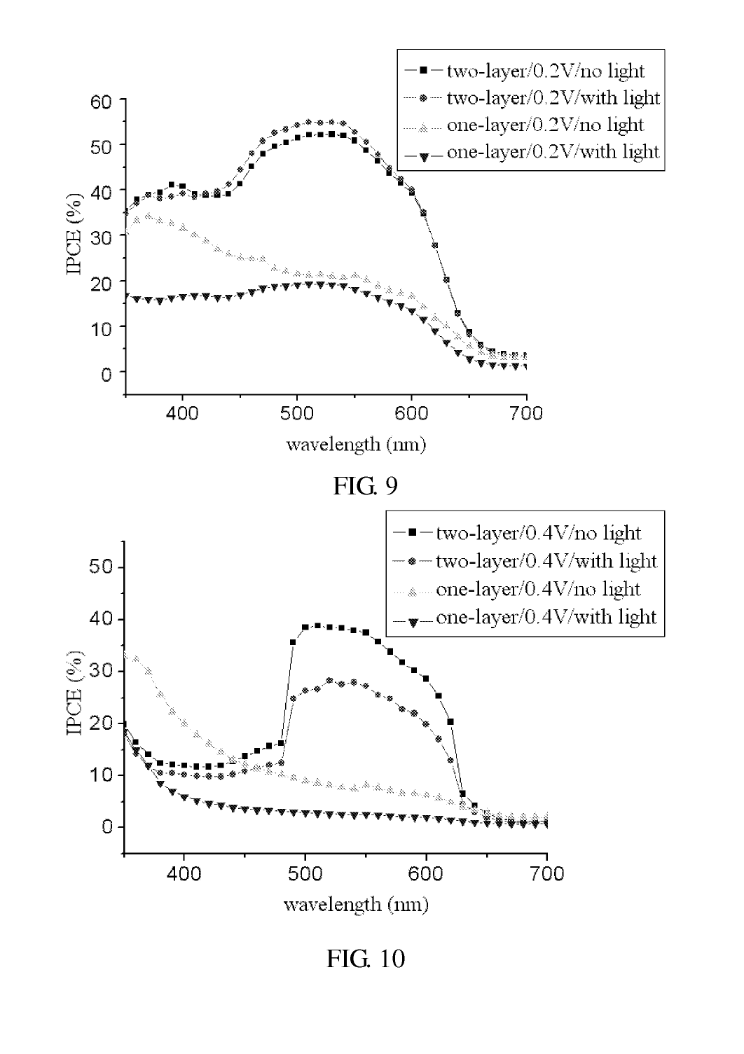

Further, the FIG. 8-10 show the relationship diagram of wavelength to incident photon-to-electron conversion efficiency (IPCE) of the two-layer and one-layer active layer structures under no bias, 0.2V bias, and 0.4V bias, and with or without light bias. Wherein, FIG. 8 provides the results of the two-layer and one-layer active layer structures without bias and with light bias. It may be observed from FIG. 8 that the external light bias has small influences on the two-layer active layer of the organic solar cell. In contrast, the one-layer active layer organic solar cell is sensitive to the external light bias. Therefore, it may be assumed that the two-layer active layer structure has better carrier extraction efficiency. Further, in FIGS. 9 and 10, although the two-layer active structure organic solar cell has gradually been influenced with gradually increased external light bias under gradually increased external bias, but the two-layer active layer structure organic solar cell provides a relative small influence of the light bias with the same bias. In other words, the two-layer active layer organic solar cell provides a higher carrier extraction efficiency. Consequently, it is obviously that the two-layer (multi-layer) active layer provides a better IPCE, carrier extraction efficiency, etc. One of the advantages of the present invention is that different active sub-layer amounts can be applied to the organic solar cell, while different thicknesses and ratios can be applied to the different sub-layers, and different solvents and materials of active layer/active sub-layer may also be applied. The apparent progress should not be obvious to the ordinary skill in the art.

Through the detailed description above, the spirit and features should be thoroughly understood by the ordinary skill in the art should. However, the details in the embodiments are only for examples and explanation. The ordinary skill in the art may make any modified according to the teaching and suggestion of the embodiments of the present invention, for meeting the various situations, and they should be viewed as in the scope of the present invention without departing the spirit of the present invention. Further the scope of the present invention should be defined by the following claims and the equivalents.

What is claimed is:

1. A method for manufacturing an organic solar cell with oriented distribution of carriers, the method comprising:
forming at least one hole transporting layer on at least one anode layer;
forming at least one active layer on said at least one hole transporting layer, wherein said at least one active layer comprises a plurality of active sub-layers; steps to form said plurality of active sub-layers comprising: (a) coating a first solution comprising electron donors and electron acceptors on said hole transporting layer, for forming a first active sub-layer; (b) forming a second solution comprising a buffer agent on said first sub-layer, for forming a non-permanent buffer layer; (c) coating a third solution comprising electron donors and electron acceptors on said non-permanent buffer layer, for forming a second active sub-layer; wherein ratio of electron donors to electron acceptors in said second active sub-layer is lower than that of said first active sub-layer; (d) repeating said steps of (b) and (c) to form said plurality of active sub-layers; and
forming at least one cathode layer on said at least one active layer.

2. The method according to claim 1, wherein said plurality of active sub-layers comprise said first active sub-layer and said second active sub-layer; wherein ratio of electron donors to electron acceptors in said first active sub-layer is between about 2.1:1 to 10:1, and ratio of electron donors to electron acceptors in said second active sub-layer is between about 2:1 to 0.5:1.

3. The method according to claim 1, wherein said plurality of active sub-layers comprise said first active sub-layer, said second active sub-layer, and a third active sub-layer; wherein ratio of electron donors to electron acceptors in said first active sub-layer is between about 2.1:1 to 10:1; ratio of electron donors to electron acceptors in said second active sub-layer is between about 2:1 to 0.5:1; and ratio of electron donors to electron acceptors in said third active sub-layer is between about 1:2.1 and 1:10.

4. The method according to claim 1, wherein said buffer agent comprises a material which does not dissolve any one of said plurality of active sub-layers.

5. The method according to claim 1, wherein said buffer agent comprises alcohol or alkane which does not dissolve organic molecules.

6. The method according to claim 1, wherein said buffer agent comprises methanol, ethanol, propanediol, glycerol, or the combinations thereof.

7. The method according to claim 1, wherein said electron donors comprise polymer.

8. The method according to claim 1, wherein said electron donors comprise organic conjugated polymer.

9. The method according to claim 1, wherein said electron donors comprise material selected from the following group: polyacetylene, polyisothianaphthene (PITN), polythiophene (PT), polypyrrol (PPr), polyfluorene (PF), poly(p-phenylene) (PPP), poly(phenylene vinylene) (PPV), poly(3-hexylthiophene-2,5-diyl) (P3HT), and the derivatives thereof.

10. The method according to claim 1, wherein said electron acceptors comprise derivatives of fullerene.

11. The method according to claim 1, wherein said steps to form said plurality of active sub-layers utilize coating method comprising cast coating, spin coating, doctor blading, screen printing, ink jet printing, pad printing, slot die coating, gravure coating, knife-over-edge coating, meniscus coating, or the combinations thereof.

12. An organic solar cell with oriented distribution of carriers, the organic solar cell comprising:
at least one anode layer;
at least one hole transporting layer formed on said at least one anode layer, for facilitating electron hole transportation;
at least one active layer formed on said at least one hole transporting layer, said at least one active layer comprising a plurality of active sub-layers; wherein each of said plurality of active sub-layers comprise electron donors and electron acceptors; ratio of electron donors to electron acceptors in one of said plurality of active sub-layers having farther distance between said at least one anode layer is lower than which in one of said plurality of active sub-layers having closer distance between said at least one anode layer, for providing oriented distribution of carriers; and
at least one cathode layer formed on said at least one active layer.

13. The organic solar cell according to claim 12, wherein said plurality of active sub-layers are formed by the following steps: (a) coating a first solution comprising electron donors and electron acceptors on said hole transporting layer, for forming a first active sub-layer; (b) forming a second solution comprising a buffer agent on said first active sub-layer, for forming a non-permanent buffer layer; (c) coating a third solution comprising electron donors and electron acceptors on said non-permanent buffer layer, for forming a second active sub-layer; wherein ratio of electron donors to electron acceptors in said second active sub-layer is lower than that of said first active sub-layer; (d) repeating said steps of (b) and (c) to form said plurality of active sub-layers.

14. The organic solar cell according to claim 12, wherein said plurality of active sub-layers comprise a first active sub-layer and a second active sub-layer; wherein ratio of electron donors to electron acceptors in said first active sub-layer is between about 2.1:1 to 10:1, and ratio of electron donors to electron acceptors is between about 2:1 to 0.5:1

15. The organic solar cell according to claim 12, wherein said plurality of active sub-layers comprise a first active sub-layer, a second active sub-layer, and a third active sub-layer; wherein ratio of electron donors to electron acceptors in said first active sub-layer is between about 2.1:1 to 10:1, ratio of electron donors to electron acceptors in said second active sub-layer is between about 2:1 to 0.5:1, and ratio of electron donors to electron acceptors in said third active sub-layer is between about 1:2.1 to 1:10.

16. The organic solar cell according to claim 12, wherein said electron donors comprise polymer.

17. The organic solar cell according to claim 12, wherein said electron donors comprise organic conjugated polymer.

18. The organic solar cell according to claim 12, wherein said electron donors comprise material selected from the following group: polyacetylene, polyisothianaphthene (PITN), polythiophene (PT), polypyrrol (PPr), polyfluorene (PF), poly(p-phenylene) (PPP), poly(phenylene vinylene) (PPV), and poly(3-hexylthiophene-2,5-diyl) (P3HT), and the derivatives thereof.

19. The organic solar cell according to claim 12, wherein said electron acceptors comprise derivatives of fullerene.

20. The organic solar cell according to claim 12, wherein said electron acceptors comprise 1-(3-methoxycarbonyl)propyl-1-phenyl[6,6]C61 (PCBM).
